(19) United States
(12) Patent Application Publication
(10) Pub. No.: US 2018/0158860 A1
(43) Pub. Date: Jun. 7, 2018

(54) STACKED IMAGE SENSOR WITH INTERCONNECTS MADE OF DOPED SEMICONDUCTOR MATERIAL

(71) Applicant: STMicroelectronics (Crolles 2) SAS, Crolles (FR)

(72) Inventor: Francois Roy, Seyssins (FR)

(73) Assignee: STMicroelectronics (Crolles 2) SAS, Crolles (FR)

(21) Appl. No.: 15/366,958

(22) Filed: Dec. 1, 2016

(51) Int. Cl. H01L 27/146; H01L 23/532; H01L 29/49

(52) U.S. Cl. CPC H01L 27/14636; H01L 27/14634; H01L 29/4916; H01L 27/14689; H01L 27/14614; H01L 23/53271

(57) ABSTRACT

An image sensor includes a first semiconductor substrate supporting a photodiode and a source region of a transfer transistor. A first interconnect level on the first semiconductor substrate includes an interconnection dielectric layer on the first semiconductor substrate and interconnect line layers over the interconnection dielectric layer. A second semiconductor substrate that supports readout transistors is mounted over the first semiconductor substrate and first interconnect level. The first interconnect level further includes a first doped semiconductor material electrical connection in physical and electrical contact with the source region in the first semiconductor substrate that passes through the interconnection dielectric layer and the interconnect line layers to electrically connect to at least one transistor of the readout transistors.

### TECHNICAL FIELD

The present disclosure relates to an image sensor, and more particularly to an image sensor using a three-dimensional (3D) stacked configuration.

### BACKGROUND

In image sensor circuits, it is a common design goal to reduce the size of each pixel so that larger pixel arrays can be formed in a given area. One solution to accomplish this goal is to implement the image sensor in a three-dimensional (3D) stacked configuration. In such a configuration, a first portion of the pixel circuit is integrated on a first semiconductor substrate and a second portion of the pixel circuit is integrated on a second semiconductor substrate. The first and second semiconductor substrates are stacked over each other with appropriate circuit interconnections formed between the two substrates.

Some processing steps used in completing overall circuit fabrication may, however, cause problems. For example, high temperature processing performed in connection with the fabrication of the circuits on the upper semiconductor substrate may detrimentally affect circuits associated with the lower semiconductor substrate. As an example, high temperature processing will cause interconnection damage like interconnect line copper migration and diffusion through the copper diffusion barrier.

### SUMMARY

In an embodiment, an image sensor comprises: a first semiconductor substrate including a photodiode and a source region of a transfer transistor; a first interconnect level on the first semiconductor substrate, said first interconnect level including: an interconnection dielectric layer on the first semiconductor substrate and a plurality of interconnection line layers over the interconnection dielectric layer; and a second semiconductor substrate supporting a plurality of readout transistors, said second semiconductor substrate mounted over the first semiconductor substrate and first interconnect level. The first interconnect level further includes a first doped semiconductor material electrical connection in physical and electrical contact with the source region in the first semiconductor substrate that passes through the interconnection dielectric layer and said plurality of interconnection line layers to electrically connect to at least one transistor of said plurality of readout transistors.

### BRIEF DESCRIPTION OF THE DRAWINGS

The foregoing and other features and advantages will be discussed in detail in the following non-limiting description of dedicated embodiments in connection with the accompanying drawings, wherein:

FIG. 1 a circuit diagram for a rolling shutter type pixel circuit for an image sensor;

FIG. 2 a circuit diagram for a global shutter type pixel circuit for an image sensor;

FIG. 3 illustrates an example partitioning of the FIG. 1 pixel circuit;

FIG. 4 illustrates an example partitioning of the FIG. 2 pixel circuit;

FIGS. 5A-5B show cross-sections of an integrated circuit transistor;

FIG. 6 shows a cross-section of an image pixel like that of FIGS. 1 and 3; and

FIG. 7A-7B show cross-sections of an image pixel like that of FIGS. 2 and 4.

### DETAILED DESCRIPTION

The same elements have been designated with the same reference numerals in the various drawings and, further, the various drawings are not to scale. For clarity, only those steps and elements which are useful to the understanding of the described embodiments have been shown and are detailed.

In the following description, terms “upper”, “lower”, “vertical”, “horizontal”, etc., refer to the orientation of the concerned elements in the corresponding drawings, it being understood that, in practice, the pixels shown in the different drawings may be oriented differently. Unless otherwise specified, term “substantially” and expression “in the order of” mean to within 10%, preferably to within 5%, and a first element “resting on” or “coating” a second element means that the first and second elements are in contact with each other.

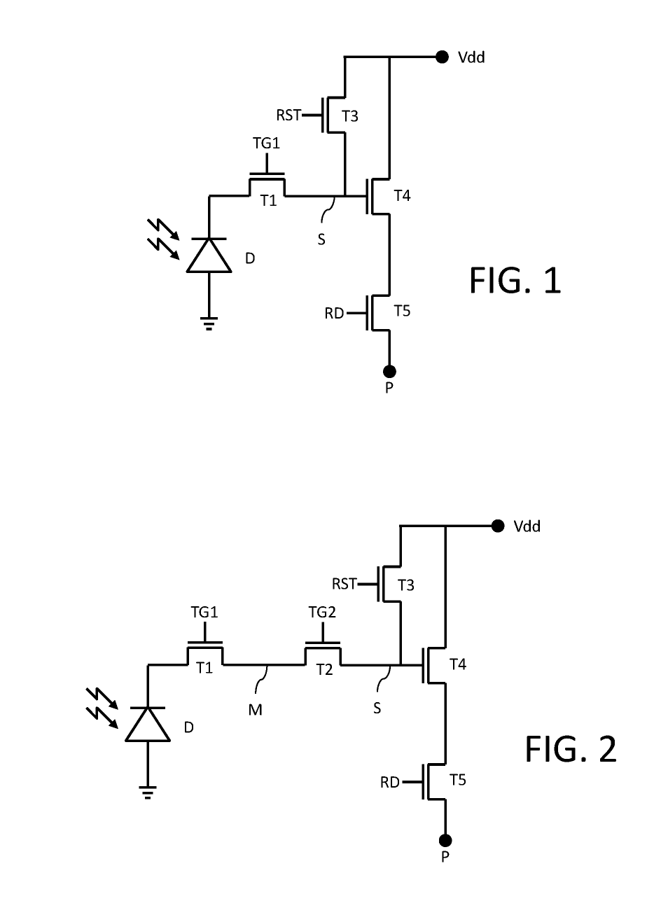

FIG. 1 shows a circuit diagram for a rolling shutter type pixel circuit for an image sensor. A photodiode D is connected to a sense node S by an N-channel MOS transfer transistor T1 having its gate connected to a terminal TG1. A read circuit comprises a reset N-channel MOS transistor T3 having its gate connected to a terminal RST, interposed between a power supply rail Vdd and sense node S, and two series-connected N-channel MOS transistors T4 and T5. The drain of transistor T4 is connected to power supply rail Vdd. The source of transistor T5 is connected to an output terminal P, itself connected to a processing circuit (not shown). The gate of transistor T4, assembled as a source follower, is connected to sense node S with the source of transistor T4 connected to the drain of transistor T5. The gate of transistor T5, configured as a read transistor, is connected to a terminal RD. Generally, the control signals at the terminals TG1, RST and RD are supplied by one or a plurality of control circuits (not shown) of the image sensor and may be supplied to all the pixels of a same row of a pixel array of the image sensor.

In operation, the pixel receives an illumination and stores photogenerated charges in the photodiode D during an integration phase. The read phase comprises a transfer operation during which transistor T1 is turned on in response to the control signal at terminal TG1, and the photogenerated charges stored in photodiode D are transferred the sense node S. Once the transfer operation has been performed, transistor T1 is turned off. The voltage of node S is then read during a read operation. This voltage is representative of the quantity of charges photogenerated during the integration phase and forms an output signal of the pixel. The voltage is passed by the source follower transistor T4 and read transistor T5 (in response to the control signal at terminal RD) to output P. Such a sensor is said to be of the rolling shutter type since the transfer operation and the read operation are carried out for all the pixels in a row before being successively carried out for the other pixel rows of the array. The rows of the array thus capture a scene but at times shifted with respect to one another.

FIG. 2 shows a circuit diagram for a global shutter type pixel circuit for an image sensor. A photodiode D is connected to a sense node S by a first N-channel MOS transfer transistor T1 having its gate connected to a terminal TG1 and a second N-channel MOS transfer transistor T2 having its gate connected to a terminal TG2. The first and second transfer transistors T1 and T2 have their source-drain paths connected in series at memory node M. A read circuit comprises a reset N-channel MOS transistor T3 having its gate connected to a terminal RST, interposed between a power supply rail Vdd and sense node S, and two series-connected N-channel MOS transistors T4 and T5. The drain of transistor T4 is connected to power supply rail Vdd. The source of transistor T5 is connected to a terminal P, itself connected to a processing circuit (not shown). The gate of transistor T4, assembled as a source follower, is connected to sense node S with the source of transistor T4 connected to the drain of transistor T5. The gate of transistor T5, configured as a read transistor, is connected to a terminal RD. Generally, the control signals at the terminals TG1, TG2, RST and RD are supplied by one or a plurality of control circuits (not shown) of the image sensor and may be supplied to all the pixels of a same row of a pixel array of the image sensor.

In operation, the pixel receives an illumination and stores photogenerated charges in the photodiode D during an integration phase. The read phase comprises a transfer operation during which transistor T1 is turned on in response to the control signal at terminal TG1, and the photogenerated charges stored in photodiode D are transferred to the memory node M. This transfer operation is simultaneously carried out for all the pixels in the array, which enables the image sensor to store a complete image in all memory nodes M of the sensor. Once the transfer operation has been performed, transistor T1 is turned off and a new integration phase may start while the read phase continues. The continuation of the read phase then comprises an additional transfer operation during which transistor T2 is turned on in response to the control signal at terminal TG2, and the charges stored in memory node M are transferred to the sense node S. The voltage of node S is then read during a read operation. This voltage is representative of the quantity of charges photogenerated during the integration phase and forms an output signal of the pixel. The voltage is passed by the source follower transistor T4 and read transistor T5 (in response to the control signal at terminal RD) to output P. Due to the fact that a complete image is stored in all the memory nodes M of the sensor, this circuitry provides images without the defects due to the time shifts which may occur in the images obtained from an image sensor of the rolling shutter type. However, as compared with a pixel of rolling shutter type, in a pixel of global shutter type it is necessary to further provide a memory node and an additional transfer transistor.

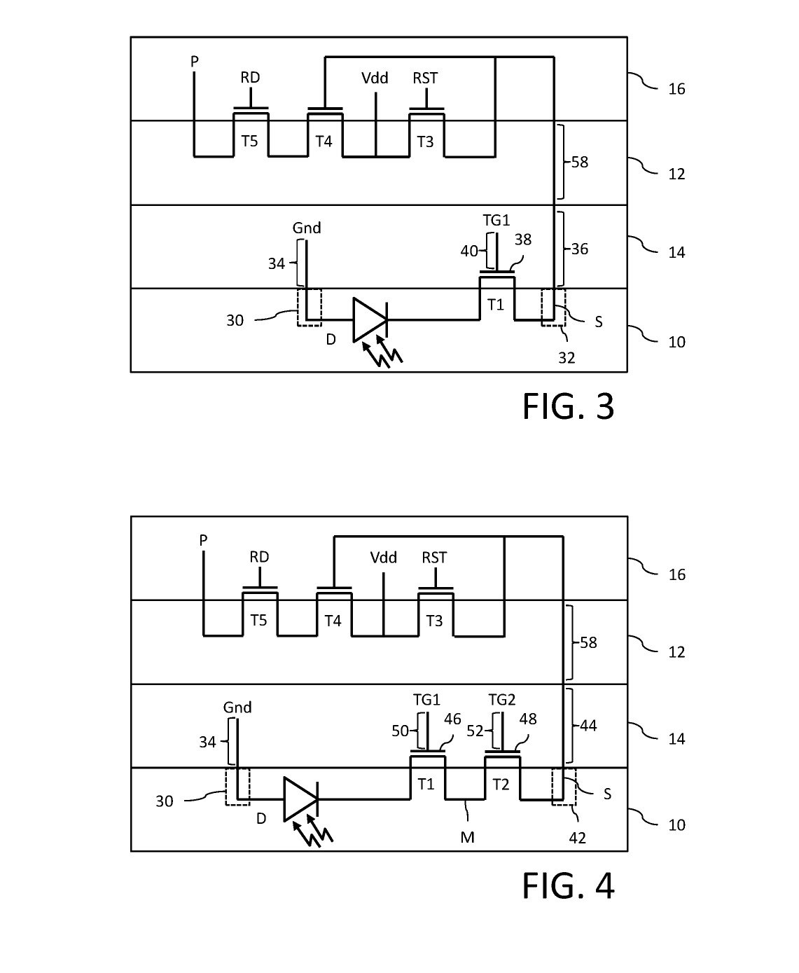

When implementing the image sensor using a three-dimensional (3D) stacked configuration, the pixel circuit must be partitioned into a first portion that is integrated on a first semiconductor substrate and a second portion that is integrated on a second semiconductor substrate. FIG. 3 illustrates an example partitioning of the FIG. 1 pixel circuit and FIG. 4 illustrates an example partitioning of the FIG. 2 pixel circuit. FIGS. 3 and 4 each include a first semiconductor substrate 10 and a second semiconductor substrate 12. The substrates 10 and 12 may be of any type (bulk, silicon-on-insulator (SOI), etc.) suitable to the given application and circuit implementation. A first interconnect level 14 is provided for the first substrate 10 and a second interconnect level 16 is provided for the second substrate 12. Each interconnect level 14 and 16 may include multiple layers (for example, an interconnection (premetallization) dielectric layer, an insulating layer, an interconnect line layer or metallization layer, etc.). The first interconnect level 14 is provided on the first semiconductor substrate 10. The second semiconductor substrate 12 is provided on the first interconnect level 14. The second interconnect level 16 is provided on the second semiconductor substrate 12.

Schematic circuit symbols with interconnections are shown in FIGS. 3 and 4 to illustrate the example circuit partitioning. The illustrated implementations are for a backside illuminated device where light is received at the bottom surface of the first substrate 10. This is, however, by example only.

With respect to FIG. 3 and the pixel circuit of FIG. 1, the doped regions/diffusions for the photodiode D and the source and drain regions of the transistor T1 and the sense node S are provided in the first semiconductor substrate 10, while the doped regions/diffusions for the source and drain regions of the transistors T3, T4 and T5 are provided in the second semiconductor substrate 12. The gate electrode for the transistor T1, as well as the electrical connections for ground (Gnd), the terminal TG1 and the sense node S, are provided in the first interconnect level 14, while the gate electrodes for the transistors T3, T4 and T5, as well as the electrical connections for the supply voltage (Vdd), the electrical connections for ground (Gnd), the terminals RST and RD, the sense node S and the output P, are provided in the second interconnect level 16.

With respect to FIG. 4 and the pixel circuit of FIG. 2, the doped regions/diffusions for the photodiode D, the source and drain regions of the transistors T1 and T2, the memory node M and the sense node S are provided in the first semiconductor substrate 10, while the doped regions/diffusions for the source and drain regions of the transistors T3, T4 and T5 are provided in the second semiconductor substrate 12. The gate electrodes for the transistors T1 and T2, as well as the electrical connections for ground (Gnd), the terminal TG1, the terminal TG2 and the sense node S, are provided in the first interconnect level 14, while the gate electrodes for the transistors T3, T4 and T5, as well as the electrical connections for the supply voltage (Vdd), the electrical connections for ground (Gnd), the terminals RST and RD, the sense node S and the output P, are provided in the second interconnect level 16.

The electrical connections in the first and second interconnect levels 14 and 16 are conventionally formed by metal materials surrounded by insulating material. For example, a tungsten plug with a silicide is typically used to make electrical contact to doped regions/diffusions of the substrates 10 and 12 in an insulating interconnection (for example, a premetallization) dielectric layer of the levels 14 and 16. Furthermore, aluminum and/or copper is typically used for wiring lines and vias to interconnect circuits to each other and to power supply lines in one or more interconnect line (for example, metallization) layers of the levels 14 and 16. See, for example, United States Patent Application Publication No. 2007/0018075 (incorporated herein by reference).

In the embodiment of FIGS. 3 and 4, however, at least the electrical connections in the first interconnect level 14 are instead provided by doped semiconductor material connections. The dopant type used for each doped semiconductor material connection matches the dopant type for the doped region/diffusion to which that doped semiconductor material connection makes physical and electrical contact.

With respect to FIG. 3, the portion of the FIG. 1 pixel circuit supported by the first substrate 10 includes, for example, a p-type doped region 30 at the anode of the photodiode D and an n-type doped region 32 at the drain of the transistor TG1. The electrical connection 34 in the first interconnect level 14 that makes physical and electrical contact with the p-type doped region 30 is accordingly made of p-type doped semiconductor material. The electrical connection 36 in the first interconnect level 14 that makes physical and electrical contact with the n-type doped region 32 is accordingly made of n-type doped semiconductor material. Furthermore, the portion of the FIG. 1 pixel circuit supported by the first interconnect level 14 includes, for example, a doped region 38 (p-type or n-type as desired by the circuit design) forming the gate electrode of transistor T1 (for example, a polysilicon gate). The electrical connection 40 in the first interconnect level 14 that makes physical and electrical contact with the doped region 38 is correspondingly made of the same type doped semiconductor material.

With respect to FIG. 4, the portion of the FIG. 2 pixel circuit supported by the first substrate 10 includes, for example, a p-type doped region 30 at the anode of the photodiode D and an n-type doped region 42 at the drain of the transistor TG2. The electrical connection 34 in the first interconnect level 14 that makes physical and electrical contact with the p-type doped region 30 is accordingly made of p-type doped semiconductor material. The electrical connection 44 in the first interconnect level 14 that makes physical and electrical contact with the n-type doped region 42 is accordingly made of n-type doped semiconductor material. Furthermore, the portion of the FIG. 1 pixel circuit supported by the first interconnect level 14 includes, for example, a doped region 46 (p-type or n-type as desired by the circuit design) forming the gate electrode of transistor T1 (for example, a polysilicon gate) and a doped region 48 (p-type or n-type as desired by the circuit design) forming the gate electrode of transistor T2 (for example, a polysilicon gate). The electrical connection 50 in the first interconnect level 14 that makes physical and electrical contact with the doped region 46 is correspondingly made of the same type doped semiconductor material. Likewise, the electrical connection 52 in the first interconnect level 14 that makes physical and electrical contact with the doped region 48 is correspondingly made of the same type doped semiconductor material.

The doped semiconductor material used for the various electrical connections (34, 36, 40, 44, 50 and 52) may comprise epitaxially grown semiconductor material, chemical vapor deposition (CVD) amorphous semiconductor material or CVD polycrystalline semiconductor material. Damascene processes using steps such as: oxide deposition, contact or trench line etching, contact or trench line doped semiconductor filling, doped semiconductor chemical mechanical polishing (CMP), etc. may be used to form the doped semiconductor material electrical connections 34, 36, 40, 44, 50 and 52.

It will be noted that the doped semiconductor material electrical connections (34, 36, 40, 44, 50 and 52) will exhibit a higher resistivity than if made instead of metal materials (tungsten, copper, aluminum) as is conventionally done in the art. However, this increased resistivity is of little concern in an image sensor circuit with response to pixel readout speed. Additionally, the advantage of using doped semiconductor material for the electrical connections (34, 36, 40, 44, 50 and 52) in the first interconnect level 14 outweighs any increased resistivity drawback because such doped semiconductor material electrical connections are compatible with subsequent high temperature (for example, >900° C.) process steps used in the fabrication of the 3D stacked configuration.

In each of the implementations shown in FIGS. 3 and 4, there is an electrical connection shown at reference 58 that must pass through the second semiconductor substrate 12. In an embodiment, this electrical connection 58 may be made of metal deposit, for example tungsten. The process techniques described in co-pending U.S. patent application Ser. No. 15/275,619 filed Sep. 26, 2016 (incorporated by reference) may be used to form the electrical connection 58. The electrical connection 58 may, for example, be made by a conductive metal plug that extends through an insulating region. In an alternative implementation, the electrical connection 58 be formed a through silicon via (TSV) structure. In an implementation of a process for producing the electrical connection 58, an etched opening is formed through the substrate 12, for example in alignment with a shallow trench isolation (STI) or other isolating structure to reach a top of the first interconnect level 14 and its doped semiconductor material electrical connection (36, 44). The etched opening is then filled with electrical connection 58 in the form of a T1 and TiN barrier with a tungsten fill.

The electrical connections in the second interconnect level 16 may be conventionally formed by metal materials surrounded by insulating material. Alternatively, the electrical connections in the second interconnect level 16 may be formed using doped semiconductor material as shown with respect to the first interconnect level 14 and described above. Again, the dopant type for the doped semiconductor material electrical connections in the second interconnect level 16 will match the dopant type for the for the doped region/diffusion of the substrate 12 or level 16 to which that doped semiconductor material connection makes physical and electrical contact.

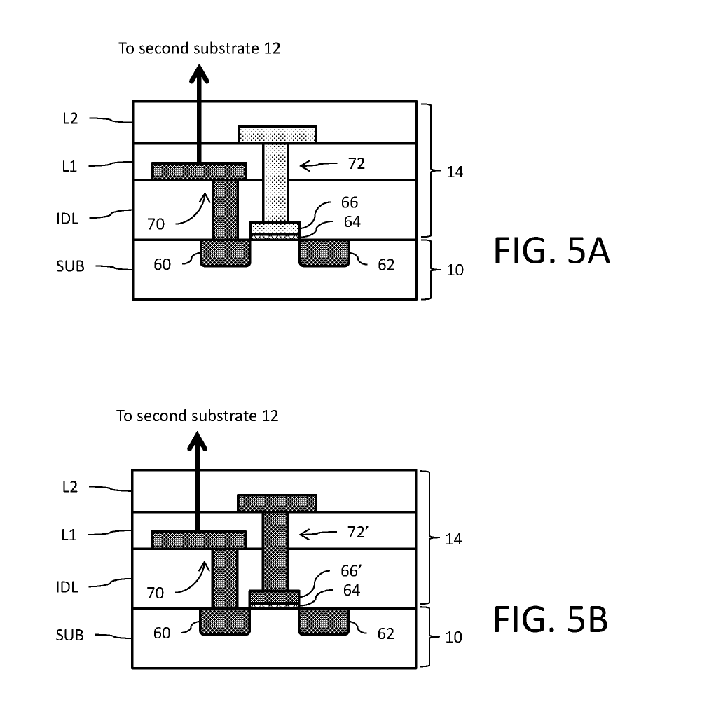

Reference is now made to FIG. 5A showing a cross-section of an integrated circuit transistor. The transistor may, for example, comprise transistor T1 or T2. The transistor is supported by a substrate (SUB) which may, for example, comprise the first substrate 10, with the substrate doped with a first type dopant (for example, p-type dopant). The substrate SUB includes doped regions/diffusions 60 and 62 forming source and drain regions for the transistor. The doped regions/diffusions 60 and 62 are doped with a second type dopant (for example, n-type dopant). A channel region of the substrate SUB is provided between the source and drain regions. A transistor gate structure is provided over the channel region. The transistor gate structure includes a gate oxide layer 64 and a gate electrode 66. The gate electrode 66 may, for example, comprise a polysilicon gate doped with the first (p) type dopant. To simply the illustration, the conventional sidewall spacers for the transistor gate structure are not shown. An interconnection (for example, premetallization) dielectric layer (IDL) is provided over the substrate SUB and transistor gate structure. On top of the interconnection dielectric layer IDL are provided a plurality of interconnection line layers L1, L2. The interconnection dielectric layer IDL and plurality of interconnection line layers L1, L2 form, for example, the first interconnect level 14.

The electrical connections in the first interconnect level 14 are provided by doped semiconductor material connections. The dopant type used for each doped semiconductor material connection matches the dopant type for the doped region/diffusion to which that doped semiconductor material connection makes physical and electrical contact. In the example of FIG. 5A, there is a first doped semiconductor material connection 70 for the transistor source region 60 that is correspondingly made of n-type doped semiconductor material (matching the dopant used for the source region 60). This first doped semiconductor material connection 70 includes a first portion passing through the interconnection dielectric layer IDL and a second portion at the first interconnection line layer L1. This first doped semiconductor material connection 70 may, for example, comprise the electrical connection 36 or 44 (and thus further extend through the second interconnection line layer L2 to reach the second substrate 12). There is also a second doped semiconductor material connection 72 for the transistor gate electrode 66 that is correspondingly made of p-type doped semiconductor material (matching the dopant used for the polysilicon gate). This second doped semiconductor material connection 72 includes a first portion passing through the interconnection dielectric layer IDL, a second portion passing through the first interconnect line layer L1 and a third portion at the second interconnection line layer L2. This second doped semiconductor material connection 72 may, for example, comprise the electrical connection 40, 50 or 52.

FIG. 5B is similar to FIG. 5A except that the gate electrode 66′ comprises a polysilicon gate instead doped with the second (n) type dopant. The second doped semiconductor material connection 72′ for the transistor gate electrode 66′ in this case is correspondingly made of n-type doped semiconductor material (matching the dopant used for the polysilicon gate). This second doped semiconductor material connection 72′ includes a first portion passing through the interconnection dielectric layer IDL, a second portion passing through the first interconnect line layer L1 and a third portion at the second interconnect line layer L2. This second doped semiconductor material connection 72′ may, for example, comprise the electrical connection 40, 50 or 52.

The routing of the doped semiconductor material connections 70, 72 and 72′ in FIGS. 5A-5B is just an example routing. It will be understood that the doped semiconductor material connections may be routed through the interconnection dielectric layer IDL and interconnect line layers L1 and L2 in any suitable manner. What is important is that the electrical connections in the first interconnect level 14 are made completely of doped semiconductor material. It will further be understood that the illustration of just two interconnect line layers is just be example and that depending on circuit complexity many more interconnect line layers may be needed. Again, what is important is that the electrical connections in the included interconnect line layers, no matter how many are used, are made completely of doped semiconductor material.

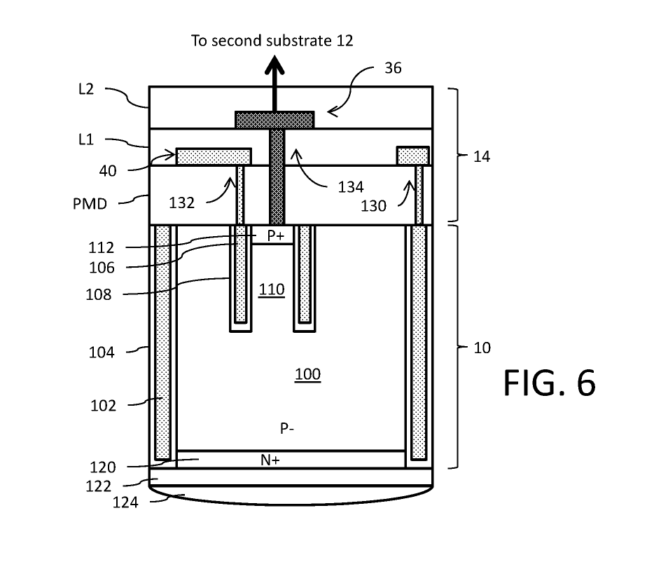

Reference is now made to FIG. 6 showing a cross-sectional view of an image sensor pixel of the rolling shutter type similar to the circuit implementation of FIGS. 1 and 3. The pixel comprises a portion of a lightly-doped (2×10¹⁵ at/cm³) p-type silicon substrate 100 (P−) laterally delimited by a conductive wall 102, insulated by an insulator 104. The conductive wall 102 comprises heavily-doped (2×10¹⁹ at/cm³) n-type material. The substrate 100 forms, for example, the first substrate 10. On the front or upper surface side of the pixel substrate and in a substantially central area of the pixel, transfer transistor T1 comprises a vertical ring-shaped gate electrode 106 insulated by an insulator 108. The insulated gate electrode 106 comprises a heavily-doped (2×10¹⁹ at/cm³) n-type material and laterally delimits a region comprising a lower lightly-doped p-type portion 110 (P−), and an upper heavily-doped (1×10²⁰ at/cm³) p-type portion 112 (P+) that functions as a charge collection area for sense node S. The lower portion or transfer area 110 extends from the charge collection area 112 down to a depth substantially equal to or smaller than that of gate electrode 106. A heavily-doped (5×10¹⁷ at/cm³) n-type layer 120 (N+) is arranged at the lower surface of substrate 100 to form the photodiode D. Further, the back side or lower surface of the pixel substrate is covered with a color filter 122 and a lens 124. This pixel is of the back-side illuminated (BSI) type.

An interconnection dielectric layer IDL is provided over the substrate 100. On top of the interconnection dielectric layer IDL are provided a plurality of interconnect line layers L1, L2. The interconnection dielectric layer ILD and plurality of interconnect line layers L1, L2 form, for example, the first interconnect level 14.

The electrical connections in the first interconnect level 14 are provided by doped semiconductor material connections. The dopant type used for each doped semiconductor material connection matches the dopant type for the doped region/diffusion to which that doped semiconductor material connection makes physical and electrical contact. In the example of FIG. 6, there is a first doped semiconductor material connection 130 for the conductive wall 102 that is made of n-type doped semiconductor material. This first doped semiconductor material connection 130 includes a first portion passing through the interconnection dielectric layer IDL and a second portion at the first interconnect line layer L1. There is also a second doped semiconductor material connection 132 for the insulated gate electrode 106 that is made of n-type doped semiconductor material. This second doped semiconductor material connection 132 includes a first portion passing through the interconnection dielectric layer IDL and a second portion at the first interconnect line layer L1 (see, FIG. 3, connection 40). There is also a third doped semiconductor material connection 134 for the charge collection area (reference 112) for sense node S that is made of p-type doped semiconductor material. This third doped semiconductor material connection 132 includes a first portion passing through the interconnection dielectric layer IDL, a second portion passing through the first interconnect line layer L1 and a third portion at the second interconnect line layer L2 and continuing to the second substrate 12 (see, FIG. 3, connection 36).

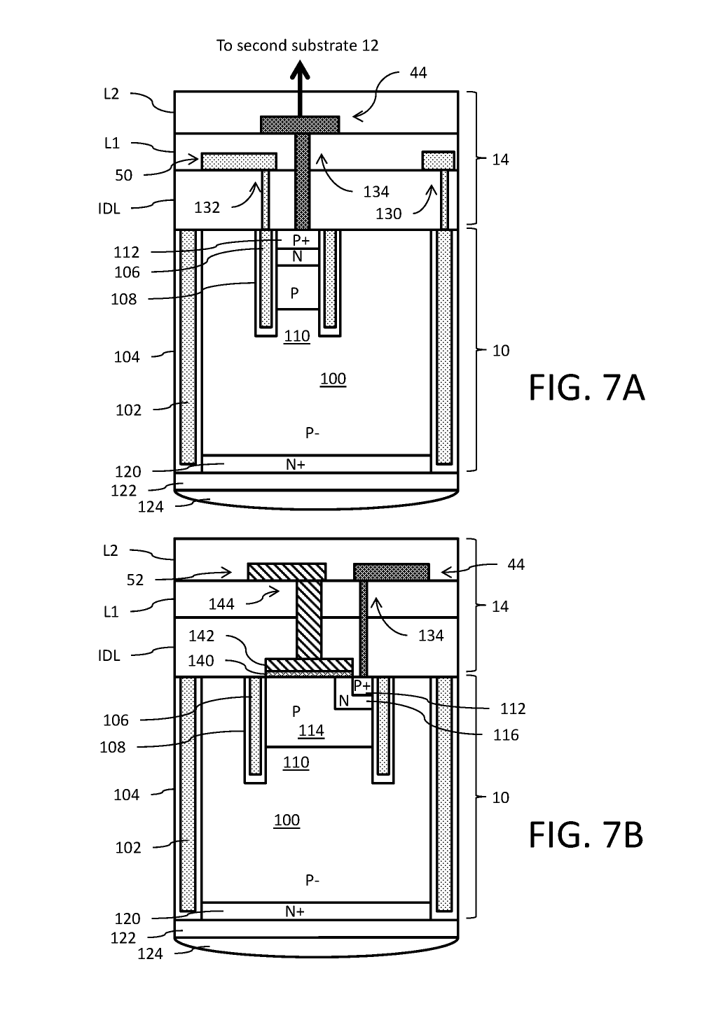

Reference is now made to FIG. 7A-7B showing orthogonal cross-sections of an image pixel of the global shutter type similar to the circuit implementation of FIGS. 2 and 4. Like reference numbers refer to like or similar components of FIG. 6. The image pixel of FIGS. 7A-7B differs from the image pixel of FIG. 6 in the following ways:

a) The insulated gate electrode 102 laterally delimits a region comprising the lower lightly-doped p-type portion 110 (P−), a p-type portion 114 (P) that functions as a charge collection area for memory node M; an intermediate n-type portion 116 (N) and the upper heavily-doped (2×10²⁰ at/cm³) p-type portion 112 (P+) formed within portion 116 that functions as a charge collection area for sense node S; and

b) A horizontal gate electrode 140 insulated from substrate 100 by a gate insulator 142 that forms the gate of transistor T2. The gate structure of electrode 140 and insulator 142 rests on the intermediate portion 116 and may extend over all or part of the memory node portion 114. The electrode 140 is formed of a doped polysilicon material.

The electrical connections in the first interconnect level 14 are provided by doped semiconductor material connections. The dopant type used for each doped semiconductor material connection matches the dopant type for the doped region/diffusion to which that doped semiconductor material connection makes physical and electrical contact. In addition to the doped semiconductor material connections 130, 132 and 134 shown in FIG. 6 (where connection 134 provides FIG. 4 connection 44), the implementation of FIGS. 7A-7B further includes a fourth doped semiconductor material connection 144 for the horizontal gate electrode 140. If the horizontal gate electrode 140 is formed of p-type doped polysilicon, the fourth doped semiconductor material connection 144 is made of p-type doped semiconductor material. Conversely, if the horizontal gate electrode 140 is formed of n-type doped polysilicon, the fourth doped semiconductor material connection 144 is made of n-type doped semiconductor material. This fourth doped semiconductor material connection 144 includes a first portion passing through the interconnection dielectric layer ILD, a second portion passing through the first interconnect line layer L1 and a third portion at the second interconnect line layer L2 and continuing to the second substrate 12 (see, FIG. 4, connection 52).

The structure disclosed herein presents a number of advantages over prior art structures including: a reduction in height of the interconnect level 14, a reduction in height of the plug connection 50, and an easier etching process for fabrication.

Various embodiments with different variations have been described hereinabove. It should be noted that those skilled in the art may combine various elements of these various embodiments and variations. Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

1. An image sensor, comprising:
a first semiconductor substrate including a photodiode and a source region of a transfer transistor;
a first interconnect level on the first semiconductor substrate, said first interconnect level including: an interconnection dielectric layer on the first semiconductor substrate and a plurality of interconnect line layers over the interconnection dielectric layer; and
a second semiconductor substrate supporting a plurality of readout transistors, said second semiconductor substrate mounted over the first semiconductor substrate and first interconnect level;
wherein the first interconnect level further includes a first doped semiconductor material electrical connection in physical and electrical contact with the source region in the first semiconductor substrate that passes through the interconnection dielectric layer and said plurality of interconnect line layers to electrically connect to at least one transistor of said plurality of readout transistors.

2. The image sensor of claim 1, wherein said source region is doped with a first type dopant and wherein said first doped semiconductor material electrical connection is made of a semiconductor material that is also doped with said first type dopant.

3. The image sensor of claim 2, wherein said semiconductor material is epitaxial semiconductor material.

4. The image sensor of claim 2, wherein said semiconductor material is polysilicon semiconductor material.

5. The image sensor of claim 2, wherein said semiconductor material is amorphous semiconductor material.

6. The image sensor of claim 1, wherein said first interconnect level further includes a gate structure of said transfer transistor, and wherein the first interconnect level further includes a second doped semiconductor material electrical connection in physical and electrical contact with a gate electrode of said gate structure that passes through the interconnection dielectric layer and at least one interconnect line layer of said plurality of interconnect line layers.

7. The image sensor of claim 6, wherein said gate electrode is made of polysilicon material doped with a first type dopant and wherein said second doped semiconductor material electrical connection is made of a semiconductor material that is also doped with said first type dopant.

8. The image sensor of claim 7, wherein said semiconductor material is epitaxial semiconductor material.

9. The image sensor of claim 7, wherein said semiconductor material is polysilicon semiconductor material.

10. The image sensor of claim 7, wherein said semiconductor material is amorphous semiconductor material.

11. The image sensor of claim 1, wherein the first doped semiconductor material electrical connection further passes through the second semiconductor substrate.

12. The image sensor of claim 11, further comprising:
a second interconnect level on the second semiconductor substrate; and
wherein said second interconnect level includes an electrical connection between the first doped semiconductor material electrical connection and said at least one transistor of said plurality of readout transistors.

13. The image sensor of claim 1,
wherein the photodiode includes a doped region; and
wherein the first interconnect level further includes a third doped semiconductor material electrical connection in physical and electrical contact with the doped region of the photodiode that passes through the interconnection dielectric layer and at least one interconnect line layer of said plurality of interconnect line layers.

14. The image sensor of claim 13, wherein said doped region of the photodiode is doped with a first type dopant and wherein said third doped semiconductor material electrical connection is made of a semiconductor material that is also doped with said first type dopant.

15. The image sensor of claim 14, wherein said semiconductor material is epitaxial semiconductor material.

16. The image sensor of claim 14, wherein said semiconductor material is polysilicon semiconductor material.

17. The image sensor of claim 14, wherein said semiconductor material is amorphous semiconductor material.

18. The image sensor of claim 1, wherein said first semiconductor substrate further includes an insulated vertical ring-shaped gate electrode for said transfer transistor, and wherein the first interconnect level further includes a fourth doped semiconductor material electrical connection in physical and electrical contact with the insulated vertical ring-shaped gate electrode that passes through the interconnection dielectric layer and at least one interconnect line layer of said plurality of interconnect line layers.

19. The image sensor of claim 18, wherein said insulated vertical ring-shaped gate electrode is made of semiconductor material doped with a first type dopant and wherein said fourth doped semiconductor material electrical connection is made of a semiconductor material that is also doped with said first type dopant.

20. The image sensor of claim 19, wherein said semiconductor material is epitaxial semiconductor material.

21. The image sensor of claim 19, wherein said semiconductor material is polysilicon semiconductor material.

22. The image sensor of claim 19, wherein said semiconductor material is amorphous semiconductor material.
